(19) United States
(12) Patent Application Publication
(10) Pub. No.: US 2014/0049271 A1
(43) Pub. Date: Feb. 20, 2014

(54) SELF-SHIELDING CO-PLANAR TOUCH SENSOR

(71) Applicant: Matthew TREND, Fareham (GB)

(72) Inventor: Matthew TREND, Fareham (GB)

(21) Appl. No.: 13/970,521

(22) Filed: Aug. 19, 2013

Related U.S. Application Data
(60) Provisional application No. 61/691,198, filed on Aug. 20, 2012.

(51) Int. Cl. G01R 27/26

(52) U.S. Cl. CPC G01R 27/2605
USPC 324/663

(57) ABSTRACT

In one embodiment, a touch sensor includes multiple first electrodes on a first surface. The first electrodes include a first shape. The touch sensor includes multiple second electrodes on a second surface. The second electrodes include a second shape. The touch sensor includes multiple third electrodes on the first surface that include a third shape that encompasses the second shape and are positioned on the first surface opposite the second electrodes. The touch sensor includes multiple fourth electrodes on the second surface that include a fourth shape that encompasses the first shape and are positioned on the second surface opposite the first electrodes.

### PRIORITY

This application claims the benefit, under 35 U.S.C. §119(e), of U.S. Provisional Patent Application No. 61/691198, filed 20 Aug. 2012, which is incorporated herein by reference.

### BACKGROUND

A touch sensor may detect the presence and location of a touch or the proximity of an object (such as a user's finger or a stylus) within a touch-sensitive area of the touch sensor overlaid on a display screen, for example. In a touch-sensitive-display application, the touch sensor may enable a user to interact directly with what is displayed on the screen, rather than indirectly with a mouse or touch pad. A touch sensor may be attached to or provided as part of a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch sensor.

There are a number of different types of touch sensors, such as (for example) resistive touch screens, surface acoustic wave touch screens, and capacitive touch screens. Herein, reference to a touch sensor may encompass a touch screen, and vice versa, where appropriate. When an object touches or comes within proximity of the surface of the capacitive touch screen, a change in capacitance may occur within the touch screen at the location of the touch or proximity. A touch-sensor controller may process the change in capacitance to determine its position on the touch screen.

### BRIEF DESCRIPTION OF THE DRAWINGS

FIG. 1 illustrates an example touch sensor 10 with an example touch-sensor controller 12.

FIGS. 2A-2B illustrate an example co-planar touchscreen design on two layers, without self-shielding.

FIGS. 3A-3C illustrate an example self-shielding co-planar touchscreen design on two layers.

FIGS. 4A-4D illustrate another example self-shielding co-planar touchscreen design on two layers.

FIGS. 5A-5D illustrate another example self-shielding co-planar touchscreen design on two layers.

FIG. 6 illustrates another example self-shielding co-planar touchscreen design on two layers.

### DESCRIPTION OF EXAMPLE EMBODIMENTS

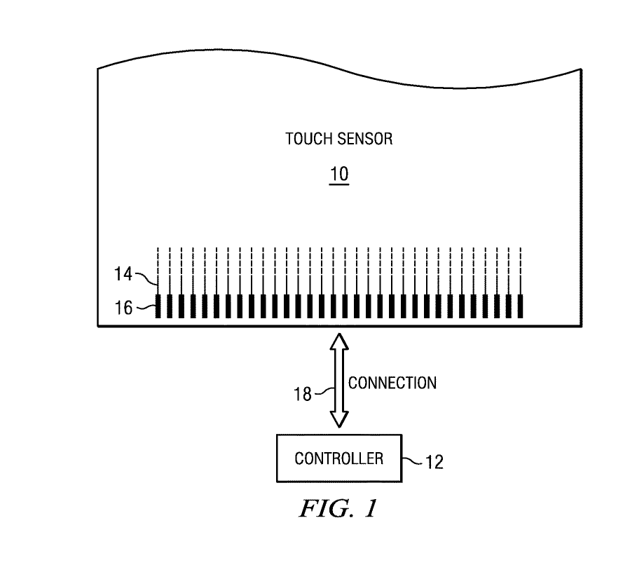

FIG. 1 illustrates an example touch sensor 10 with an example touch-sensor controller 12. Touch sensor 10 and touch-sensor controller 12 may detect the presence and location of a touch or the proximity of an object within a touch-sensitive area of touch sensor 10. Herein, reference to a touch sensor may encompass both the touch sensor and its touch-sensor controller, where appropriate. Similarly, reference to a touch-sensor controller may encompass both the touch-sensor controller and its touch sensor, where appropriate. Touch sensor 10 may include one or more touch-sensitive areas, where appropriate. Touch sensor 10 may include an array of drive and sense electrodes (or an array of electrodes of a single type) disposed on one or more substrates, which may be made of a dielectric material. Herein, reference to a touch sensor may encompass both the electrodes of the touch sensor and the substrate(s) that they are disposed on, where appropriate. Alternatively, where appropriate, reference to a touch sensor may encompass the electrodes of the touch sensor, but not the substrate(s) that they are disposed on. Herein, reference to a touchscreen may encompass a touch sensor, and vice versa, where appropriate.

An electrode (whether a ground electrode, a guard electrode, a drive electrode, a sense electrode, or other appropriate electrode) may be an area of conductive material forming a shape, such as for example a disc, square, rectangle, thin line, other suitable shape, or suitable combination of these. One or more cuts in one or more layers of conductive material may (at least in part) create the shape of an electrode, and the area of the shape may (at least in part) be bounded by those cuts. In particular embodiments, the conductive material of an electrode may occupy approximately 100% of the area of its shape. As an example and not by way of limitation, an electrode may be made of indium tin oxide (ITO) and the ITO of the electrode may occupy approximately 100% of the area of its shape (sometimes referred to as 100% fill), where appropriate. In particular embodiments, the conductive material of an electrode may occupy substantially less than 100% of the area of its shape. As an example and not by way of limitation, an electrode may be made of fine lines of metal or other conductive material (FLM), such as for example copper, silver, or a copper- or silver-based material, and the fine lines of conductive material may occupy approximately 5% of the area of its shape in a hatched, mesh, or other suitable pattern. Herein, reference to FLM encompasses such material, where appropriate. Although this disclosure describes or illustrates particular electrodes made of particular conductive material forming particular shapes with particular fill percentages having particular patterns, this disclosure contemplates any suitable electrodes made of any suitable conductive material forming any suitable shapes with any suitable fill percentages having any suitable patterns.

Where appropriate, the shapes of the electrodes (or other elements) of a touch sensor may constitute in whole or in part one or more macro-features of the touch sensor. One or more characteristics of the implementation of those shapes (such as, for example, the conductive materials, fills, or patterns within the shapes) may constitute in whole or in part one or more micro-features of the touch sensor. One or more macro-features of a touch sensor may determine one or more characteristics of its functionality, and one or more micro-features of the touch sensor may determine one or more optical features of the touch sensor, such as for example transmittance, refraction, or reflection.

A mechanical stack may contain the substrate (or multiple substrates) and the conductive material forming the drive or sense electrodes of touch sensor 10. As an example and not by way of limitation, the mechanical stack may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with the conductive material, which may be deposited on the surface of the substrate, forming the drive or sense electrodes. The mechanical stack may also include a second layer of OCA and a dielectric layer (which may be made of polyethylene terephthalate (PET) or another suitable material, similar to the substrate with the conductive material forming the drive or sense electrodes). As an alternative, where appropriate, a thin coating of a dielectric material may be applied instead of the second layer of OCA and the dielectric layer. The second layer of OCA may be disposed between the substrate with the conductive material making up the drive or sense electrodes and the dielectric layer, and the dielectric layer may be disposed between the second layer of OCA and an air gap to a display of a device including touch sensor 10 and touch-sensor controller 12. As an example only and not by way of limitation, the cover panel may have a thickness of approximately 1 mm; the first layer of OCA may have a thickness of approximately 0.05 mm; the substrate with the conductive material forming the drive or sense electrodes may have a thickness of approximately 0.05 mm; the second layer of OCA may have a thickness of approximately 0.05 mm; and the dielectric layer may have a thickness of approximately 0.05 mm. Although this disclosure describes a particular mechanical stack with a particular number of particular layers made of particular materials and having particular thicknesses, this disclosure contemplates any suitable mechanical stack with any suitable number of any suitable layers made of any suitable materials and having any suitable thicknesses. As an example and not by way of limitation, in particular embodiments, a layer of adhesive or dielectric may replace the dielectric layer, second layer of OCA, and air gap described above, with there being no air gap to the display.

One or more portions of the substrate of touch sensor 10 may be made of PET or another suitable material. This disclosure contemplates any suitable substrate with any suitable portions made of any suitable material. In particular embodiments, the drive or sense electrodes in touch sensor 10 may be made of ITO in whole or in part. In particular embodiments, the drive or sense electrodes in touch sensor 10 may be made of fine lines of metal or other conductive material. As an example and not by way of limitation, one or more portions of the conductive material may be copper or copper-based and have a thickness of approximately 5 μm or less and a width of approximately 10 μm or less. As another example, one or more portions of the conductive material may be silver or silver-based and similarly have a thickness of approximately 5 μm or less and a width of approximately 10 μm or less. This disclosure contemplates any suitable electrodes made of any suitable material.

Touch sensor 10 may implement a capacitive form of touch sensing. In a mutual-capacitance implementation, touch sensor 10 may include an array of drive and sense electrodes forming an array of capacitive nodes. A drive electrode and a sense electrode may form a capacitive node. The drive and sense electrodes forming the capacitive node may come near each other, but not make electrical contact with each other. Instead, the drive and sense electrodes may be capacitively coupled to each other across a space between them. A pulsed or alternating voltage may be applied to the drive electrode (by touch-sensor controller 12), which may induce a charge on the sense electrode, and the amount of charge induced may be susceptible to external influence (such as a touch or the proximity of an object). When an object touches or comes within proximity of the capacitive node, a change in capacitance may occur at the capacitive node and touch-sensor controller 12 may measure the change in capacitance. By measuring changes in capacitance throughout the array, touch-sensor controller 12 may determine the position of the touch or proximity within the touch-sensitive area(s) of touch sensor 10.

In a self-capacitance implementation, touch sensor 10 may include an array of electrodes of a single type that may each form a capacitive node. When an object touches or comes within proximity of the capacitive node, a change in self-capacitance may occur at the capacitive node and touch-sensor controller 12 may measure the change in capacitance, for example, as a change in the amount of charge needed to raise the voltage at the capacitive node by a pre-determined amount. As with a mutual-capacitance implementation, by measuring changes in capacitance throughout the array, touch-sensor controller 12 may determine the position of the touch or proximity within the touch-sensitive area(s) of touch sensor 10. This disclosure contemplates any suitable form of capacitive touch sensing, where appropriate.

In particular embodiments, one or more drive electrodes may together form a drive line running horizontally or vertically or in any suitable orientation. Similarly, one or more sense electrodes may together form a sense line running horizontally or vertically or in any suitable orientation. In particular embodiments, drive lines may run substantially perpendicular to sense lines. Herein, reference to a drive line may encompass one or more drive electrodes making up the drive line, and vice versa, where appropriate. Similarly, reference to a sense line may encompass one or more sense electrodes making up the sense line, and vice versa, where appropriate.

Touch sensor 10 may have drive and sense electrodes disposed in a pattern on one side of a single substrate. In such a configuration, a pair of drive and sense electrodes capacitively coupled to each other across a space between them may form a capacitive node. For a self-capacitance implementation, electrodes of only a single type may be disposed in a pattern on a single substrate. Herein, reference to a touchscreen design on one layer (or a single layer) may encompass a mutual-capacitance touch sensor 10 with both drive and sense electrodes disposed on one side of a single substrate, where appropriate. Similarly, reference to a touchscreen design on one layer (or a single layer) may encompass a self-capacitance touch sensor 10 with all its drive electrodes disposed on one side of a single substrate, where approriate. In addition or as an alternative to having drive and sense electrodes disposed in a pattern on one side of a single substrate, touch sensor 10 may have drive electrodes disposed in a pattern on one side of a substrate and sense electrodes disposed in a pattern on another side of the substrate. Moreover, touch sensor 10 may have drive electrodes disposed in a pattern on one side of one substrate and sense electrodes disposed in a pattern on one side of another substrate. In such configurations, an intersection of a drive electrode and a sense electrode may form a capacitive node. Such an intersection may be a location where the drive electrode and the sense electrode “cross” or come nearest each other in their respective planes. The drive and sense electrodes do not make electrical contact with each other—instead they are capacitively coupled to each other across a dielectric at the intersection. Herein, reference to a touchscreen design on two layers (or dual layers) may encompass a mutual-capacitance touch sensor 10 with drive electrodes disposed on a first surface of one substrate and sense electrodes disposed on a second surface of the same substrate that is opposite the first surface, where appropriate. Reference to a touchscreen design on two layers (or dual layers) may also encompass a mutual-capacitance touch sensor 10 with drive electrodes disposed on one surface of one substrate and sense electrodes disposed on one surface of another substrate, where appropriate. Herein, reference to a “side” may encompass a “surface,” and vice versa, where appropriate. Although this disclosure describes particular configurations of particular electrodes forming particular nodes, this disclosure contemplates any suitable configuration of any suitable electrodes forming any suitable nodes. Moreover, this disclosure contemplates any suitable electrodes disposed on any suitable number of any suitable substrates in any suitable patterns.

As described above, a change in capacitance at a capacitive node of touch sensor 10 may indicate a touch or proximity input at the position of the capacitive node. Touch-sensor controller 12 may detect and process the change in capacitance to determine the presence and location of the touch or proximity input. Touch-sensor controller 12 may then communicate information about the touch or proximity input to one or more other components (such one or more central processing units (CPUs)) of a device that includes touch sensor 10 and touch-sensor controller 12, which may respond to the touch or proximity input by initiating a function of the device (or an application running on the device). Although this disclosure describes a particular touch-sensor controller having particular functionality with respect to a particular device and a particular touch sensor, this disclosure contemplates any suitable touch-sensor controller having any suitable functionality with respect to any suitable device and any suitable touch sensor.

Touch-sensor controller 12 may be one or more integrated circuits (ICs), such as for example general-purpose microprocessors, microcontrollers, programmable logic devices or arrays, application-specific ICs (ASICs). In particular embodiments, touch-sensor controller 12 comprises analog circuitry, digital logic, and digital non-volatile memory. In particular embodiments, touch-sensor controller 12 is disposed on a flexible printed circuit (FPC) bonded to the substrate of touch sensor 10, as described below. The FPC may be active or passive, where appropriate. In particular embodiments, multiple touch-sensor controllers 12 are disposed on the FPC. Touch-sensor controller 12 may include a processor unit, a drive unit, a sense unit, and a storage unit. The drive unit may supply drive signals to the drive electrodes of touch sensor 10. The sense unit may sense charge at the capacitive nodes of touch sensor 10 and provide measurement signals to the processor unit representing capacitances at the capacitive nodes. The processor unit may control the supply of drive signals to the drive electrodes by the drive unit and process measurement signals from the sense unit to detect and process the presence and location of a touch or proximity input within the touch-sensitive area(s) of touch sensor 10. The processor unit may also track changes in the position of a touch or proximity input within the touch-sensitive area(s) of touch sensor 10. The storage unit may store programming for execution by the processor unit, including programming for controlling the drive unit to supply drive signals to the drive electrodes, programming for processing measurement signals from the sense unit, and other suitable programming, where appropriate. Although this disclosure describes a particular touch-sensor controller having a particular implementation with particular components, this disclosure contemplates any suitable touch-sensor controller having any suitable implementation with any suitable components.

Tracks 14 of conductive material disposed on the substrate of touch sensor 10 may couple the drive or sense electrodes of touch sensor 10 to connection pads 16, also disposed on the substrate of touch sensor 10. As described below, connection pads 16 facilitate coupling of tracks 14 to touch-sensor controller 12. Tracks 14 may extend into or around (e.g. at the edges of) the touch-sensitive area(s) of touch sensor 10. Particular tracks 14 may provide drive connections for coupling touch-sensor controller 12 to drive electrodes of touch sensor 10, through which the drive unit of touch-sensor controller 12 may supply drive signals to the drive electrodes. Other tracks 14 may provide sense connections for coupling touch-sensor controller 12 to sense electrodes of touch sensor 10, through which the sense unit of touch-sensor controller 12 may sense charge at the capacitive nodes of touch sensor 10. Tracks 14 may be made of fine lines of metal or other conductive material. As an example and not by way of limitation, the conductive material of tracks 14 may be copper or copper-based and have a width of approximately 100 μm or less. As another example, the conductive material of tracks 14 may be silver or silver-based and have a width of approximately 100 μm or less. In particular embodiments, tracks 14 may be made of ITO in whole or in part in addition or as an alternative to fine lines of metal or other conductive material. Although this disclosure describes particular tracks made of particular materials with particular widths, this disclosure contemplates any suitable tracks made of any suitable materials with any suitable widths. In addition to tracks 14, touch sensor 10 may include one or more ground lines terminating at a ground connector (which may be a connection pad 16) at an edge of the substrate of touch sensor 10 (similar to tracks 14).

Connection pads 16 may be located along one or more edges of the substrate, outside the touch-sensitive area(s) of touch sensor 10. As described above, touch-sensor controller 12 may be on an FPC. Connection pads 16 may be made of the same material as tracks 14 and may be bonded to the FPC using an anisotropic conductive film (ACF). Connection 18 may include conductive lines on the FPC coupling touch-sensor controller 12 to connection pads 16, in turn coupling touch-sensor controller 12 to tracks 14 and to the drive or sense electrodes of touch sensor 10. In another embodiment, connection pads 16 may be connected to an electro-mechanical connector (such as a zero insertion force wire-to-board connector); in this embodiment, connection 18 may not need to include an FPC. This disclosure contemplates any suitable connection 18 between touch-sensor controller 12 and touch sensor 10.

Particular embodiments provide a self-shielding co-planar touchscreen pattern (such as, for example, a snowflake or diamond pattern) on two layers. Herein, reference to a touchscreen may encompass a touch sensor, and vice versa, where appropriate.

A diamond pattern on two layers (such as two layers of PET) may be shielded against display noise and lens bending by applying ground in spaces on the bottom layer and floating areas on the top layer. Floating areas may also be referred to herein as floating regions. The bottom-layer electrodes may be drive (or “X” or “Tx”) electrodes, which do not pick up display noise, and may capacitively couple with floating areas on the top layer, effectively making the floating areas on the top layer X electrodes, which are referred to herein as floating electrodes, where appropriate. A touch sensor with such a design may have reduced lens bending, as the capacitive field Cm is projected only forwards.

Previous co-planar patterns (such as snowflake and diamond patterns) on two layers of PET typically require a ground shield, a quiet display, or algorithms that take up valuable time and power to cancel display noise. For lens bending, these two-layer patterns may also be affected by bending of the lens in relation to the display behind. A ground shield may be expensive, take up valuable space, and reduce transmission. Full lamination may also be expensive and still require the use of noise-canceling algorithms. Moreover, these approaches may be incompatible with substantially flexible front panels. Particular embodiments provide an approach to shielding co-planar patterns that resolves or reduces these issues. Also, ITO replacements sometimes need to be lasered, which means floating areas may be necessary to keep down processing time.

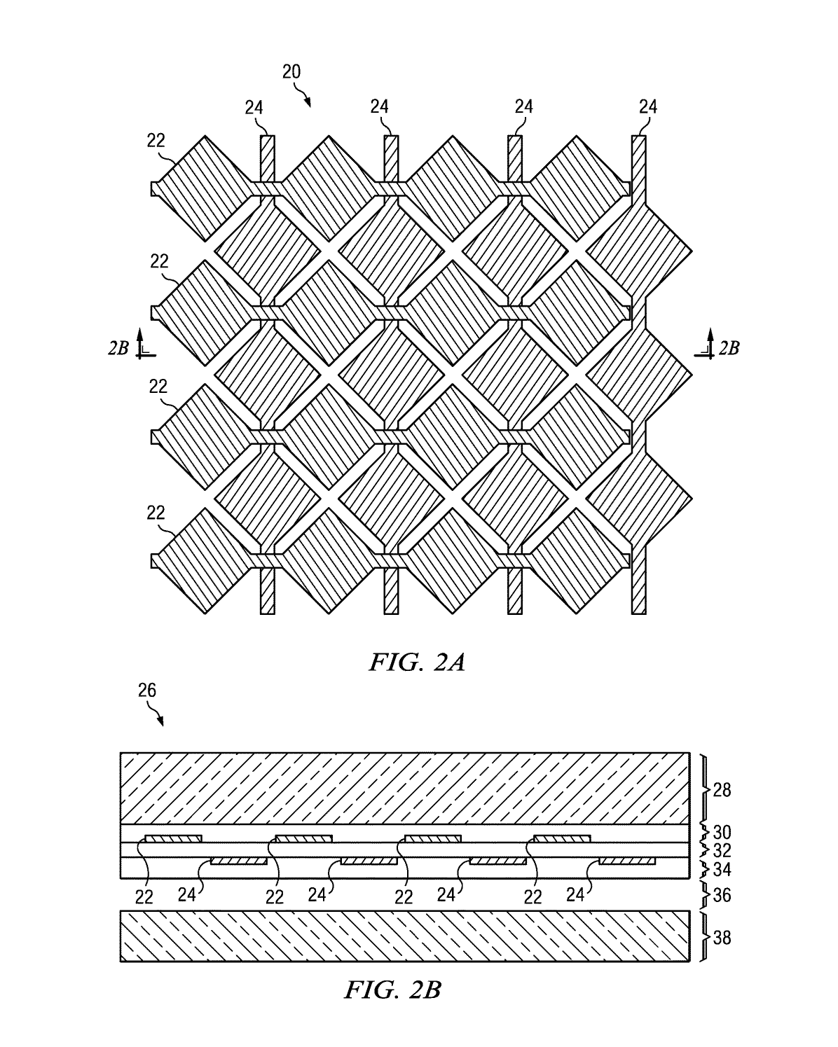

FIGS. 2A-2B illustrate an example co-planar touchscreen design 20 on two layers, without self-shielding. Touchscreen design 20 includes an example diamond pattern. In touchscreen design 20, a top layer includes sense (or “Y”) electrodes 22 and a bottom layer includes X electrodes 24. FIG. 2A provides a top-down view of touchscreen design 20, and FIG. 2B provides a cross-section view of an example mechanical stack 26 including touchscreen design 20. Mechanical stack 26 includes a front panel 28, a first adhesive/protective layer 30, a layer of PET 32 with a layer of Y electrodes 22 on the surface of one side and a layer X electrodes 24 on the surface of another side, a second adhesive/protective layer 34, an air gap 36, and a display 38. Although this disclosure describes and illustrates a particular mechanical stack 26, this disclosure contemplates any suitable mechanical stack 26.

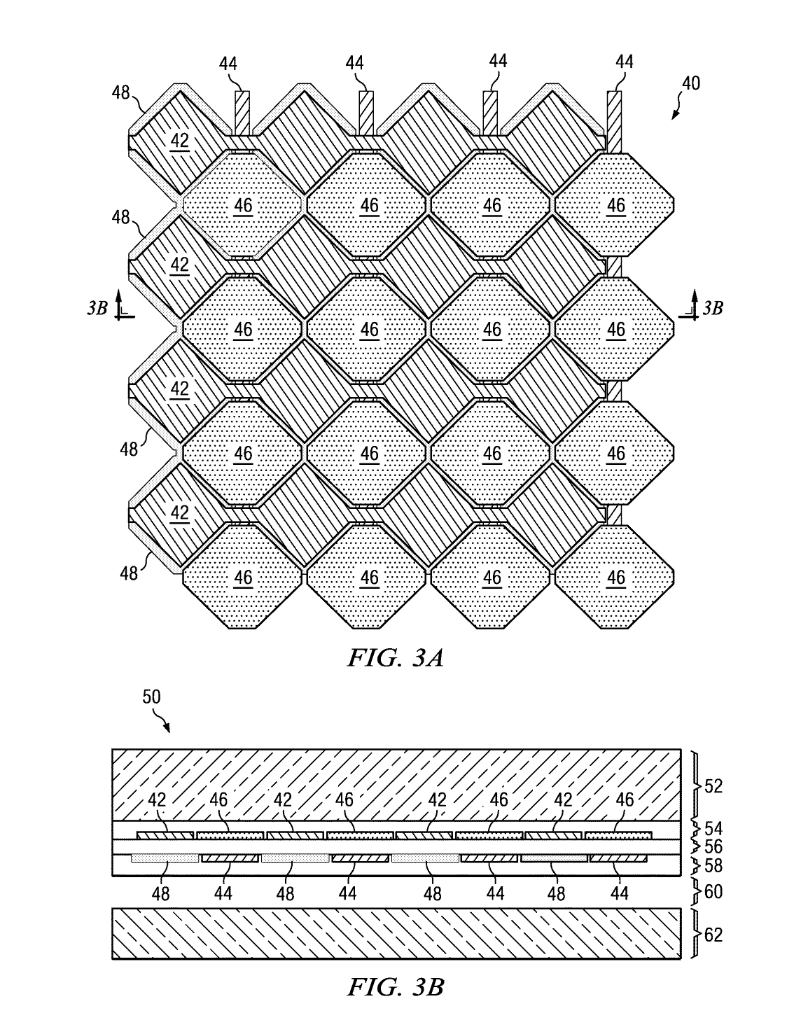

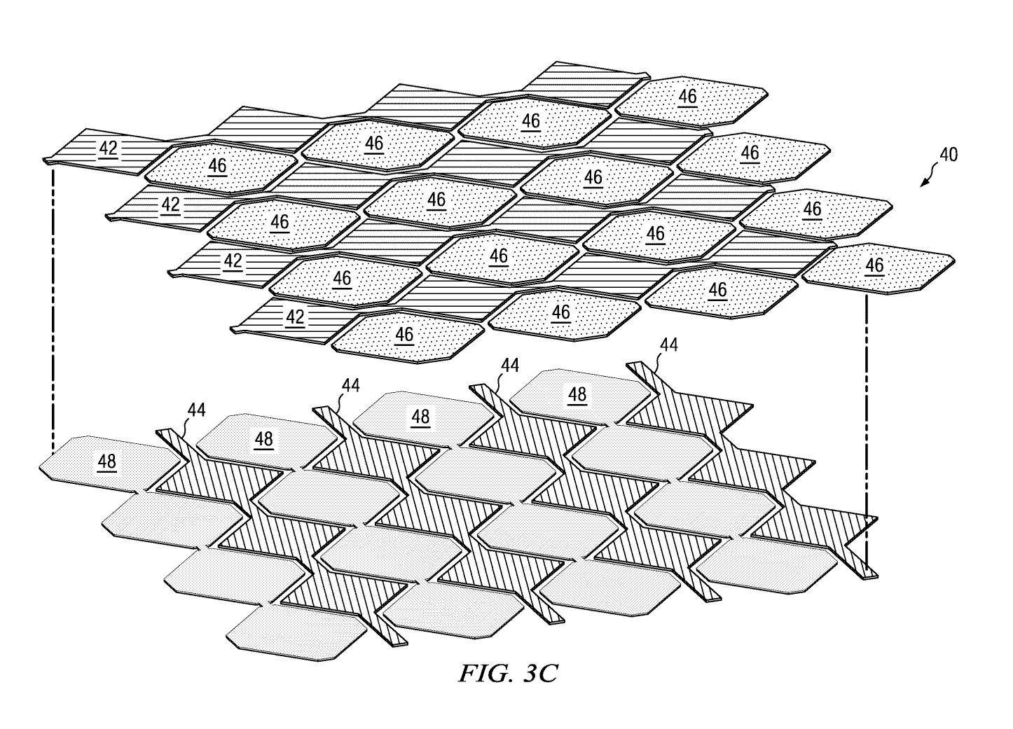

FIGS. 3A-3C illustrate an example self-shielding co-planar touchscreen design 40 on two layers. FIG. 3A provides a top-down view of touchscreen design 40, FIG. 3B provides a cross-section view of an example mechanical stack 50 including touchscreen design 40, and FIG. 3C provides an exploded top-down view of touchscreen design 40. Touchscreen design 40 includes an example diamond pattern. In touchscreen design 40, a top layer includes Y electrodes 42 and a bottom layer includes X electrodes 44. The top layer also includes floating electrodes 46, and the bottom layer also includes ground electrodes 48. Floating electrodes 46 and ground electrodes 48 may be made of the same material as Y and X electrodes 42 and 44. The material on the top layer may be cut or etched to form the pattern of Y electrodes 42 and floating electrodes 46 in the example of FIGS. 3A-3C, and the material on the bottom layer may be similarly cut or etched to form the pattern of X electrodes 44 and ground electrodes 48 in the example of FIGS. 3A-3C. In particular embodiments, layers that may be cut or etched to form electrodes may (at least in part) be substantially continuous, such that the layer (or part thereof) consists of one piece across the entirety of the layer (or part thereof), as opposed to two or more pieces combined, conjoined, or otherwise arranged together to form one layer (or part thereof). Each floating electrode 46 may be positioned opposite to a respective X electrode 44, and ground electrodes 48 may be positioned opposite to and provide shielding for a respective Y electrode 42. In particular embodiments, positioning a floating electrode 46 opposite to an X electrode 44 may allow for more consistent coupling between X electrode 44 and Y electrode 42, which may improve consistency associated with touchscreen design 40. In particular embodiments, floating electrodes 46 may be of a size that encompasses X electrodes 44 such that, from the top-down perspective provided by FIG. 3C, the perimeter of the shape of each X electrode 44 does not extend past the perimeter of the shape of each corresponding floating electrode 46, which may improve an alignment tolerance between the X electrodes 44 and the floating electrodes 46. In particular embodiments, the shape of the floating electrodes 46 may be the equivalent shape of X electrodes 44 and of an equivalent size to the shape of X electrodes 44. In particular embodiments, the shape of floating electrodes 46 may be the equivalent shape of X electrodes 44 but larger than the shape of X electrodes 44. By way of example, and not by way of limitation, floating electrodes 46 may be a diamond shape that is equivalent to a diamond shape of X electrodes 44, but the diamond shape of floating electrodes 46 may be larger than the diamond shape of X electrodes 44. In another example, floating electrodes 46 may be a snowflake shape that is equivalent to a snowflake shape of X electrodes 44, but the snowflake shape of floating electrodes 46 may be larger than the snowflake shape of X electrodes 44. In particular embodiments, the shape of floating electrodes 46 may not be the equivalent shape of X electrodes 44. In particular embodiments, the size of the shape of floating electrodes 46 may be of an equivalent size to the shape of X electrodes 44. In particular embodiments, ground electrodes 48 may be of a size that encompasses Y electrodes 42 such that, from the top-down perspective provided by FIG. 3C, the perimeter of the shape of each Y electrode 42 does not extend past the perimeter of the shape of each corresponding ground electrode 48, which provides better shielding. In particular embodiments, the shape of the ground electrodes 48 may be the equivalent shape of Y electrodes 42 and of an equivalent size to the shape of Y electrodes 42. In particular embodiments, the shape of ground electrodes 48 may be the equivalent shape of Y electrodes 42 but larger than the shape of Y electrodes 42. By way of example, and not by way of limitation, ground electrodes 48 may be a diamond shape that is equivalent to a diamond shape of Y electrodes 42, but the diamond shape of ground electrodes 48 may be larger than the diamond shape of Y electrodes 42. In another example, ground electrodes 48 may be a snowflake shape that is equivalent to a snowflake shape of Y electrodes 42, but the snowflake shape of ground electrodes 48 may be larger than the snowflake shape of Y electrodes 42. In particular embodiments, the shape of ground electrodes 48 may not be the equivalent shape of Y electrodes 42. In particular embodiments, the size of the shape of ground electrodes 48 may be of an equivalent size to the shape of Y electrodes 42. Floating electrodes 46 are cut or etched to be electrically isolated. Ground electrodes 48 are cut or etched to form lines running parallel to X electrodes 44.

Mechanical stack 50 in the example of FIG. 3B includes a front panel 52; a first adhesive/protective layer 54; a layer of PET 56 with a layer of Y electrodes 42 and floating electrodes 46 on the surface of one side of the layer of PET 56 and a layer of X electrodes 44 and ground electrodes 48 on the surface of another side of the layer of PET 56; a second adhesive/protective layer 58; an air gap 60; and a display 62. Although this disclosure describes and illustrates a particular mechanical stack 50, this disclosure contemplates any suitable mechanical stack 50.

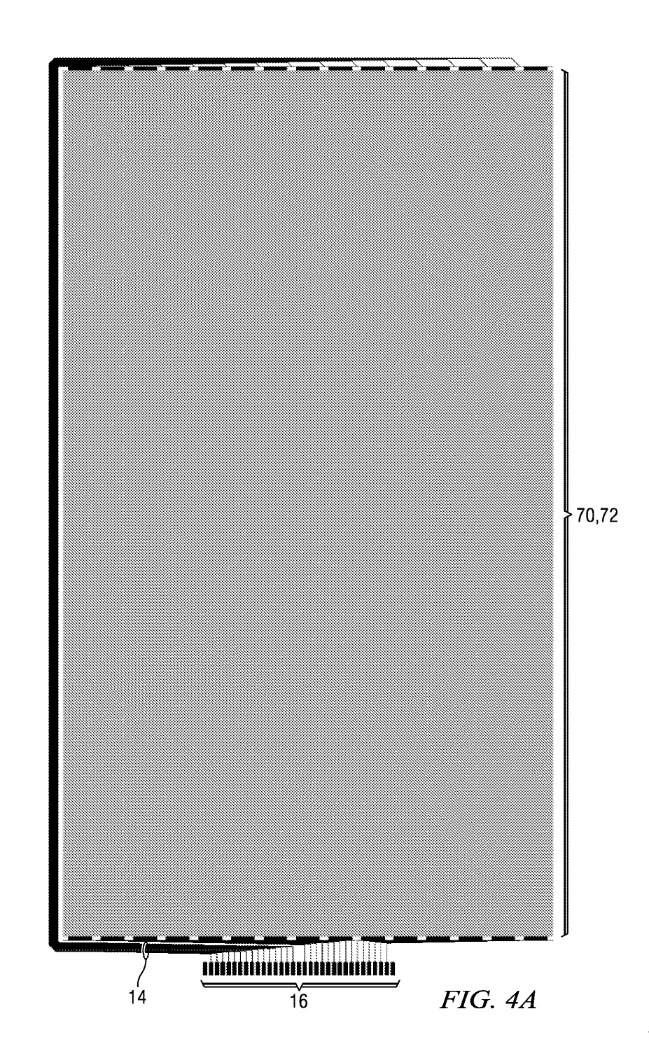

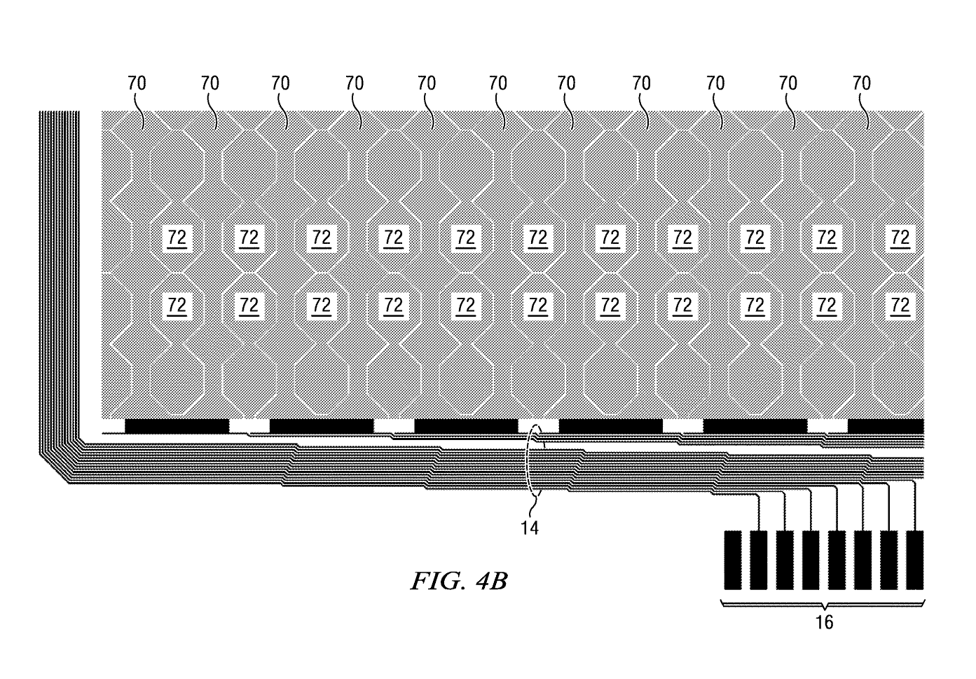

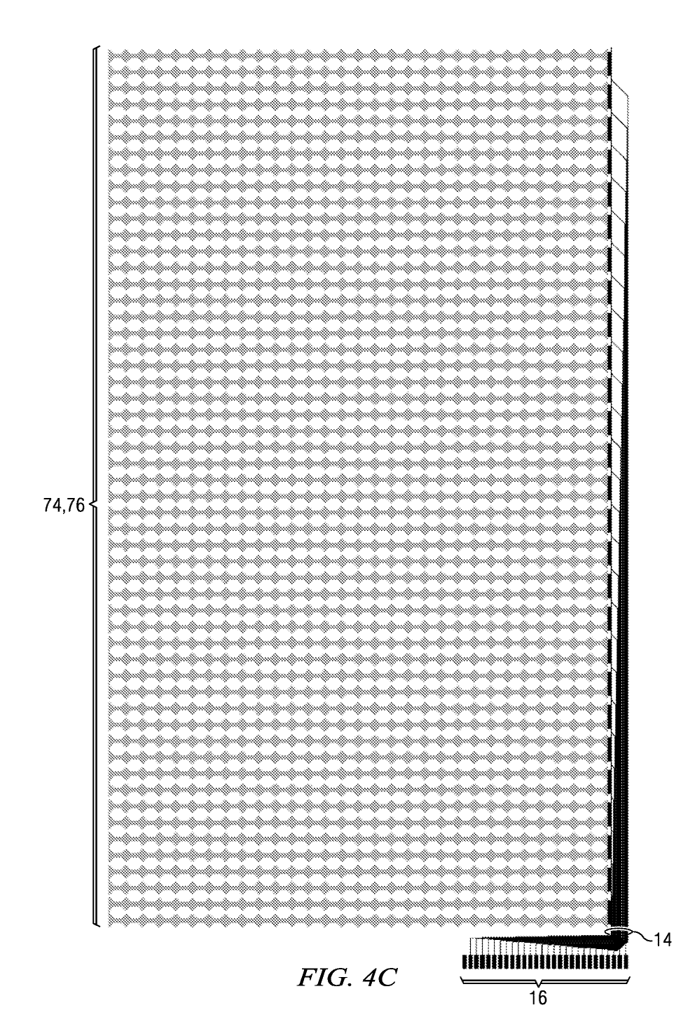

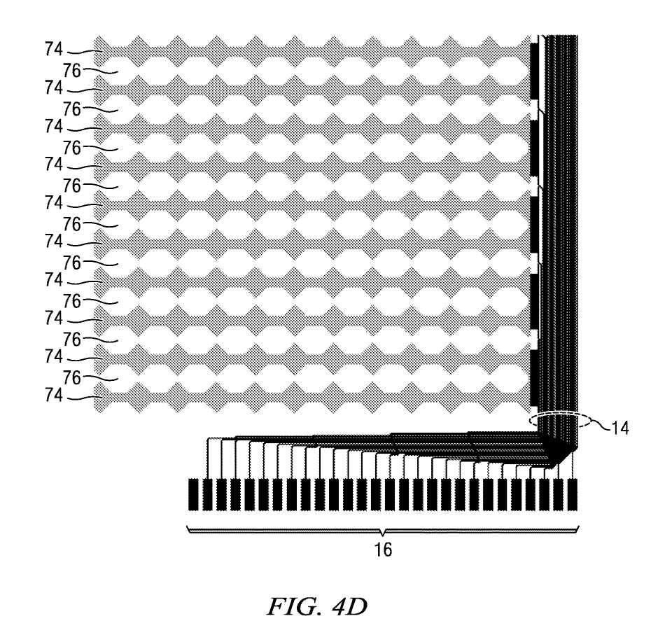

FIGS. 4A-4D illustrate another example self-shielding co-planar touchscreen design on two layers. The touchscreen design of FIGS. 4A-4D includes an example diamond pattern. FIG. 4A illustrates a top layer of the design, and FIG. 4B provides a close-up view of a portion of the top layer in FIG. 4A. FIG. 4C illustrates a bottom layer of the design, and FIG. 4D provides a close-up view of a portion of the bottom layer in FIG. 4C. In the example of FIGS. 4A-4D, the top layer of the design (illustrated by FIGS. 4A-4B) includes Y electrodes 70 and floating electrodes 72. The bottom layer of the design (illustrated by FIGS. 4C-4D) includes X electrodes 74 and ground electrodes 76.

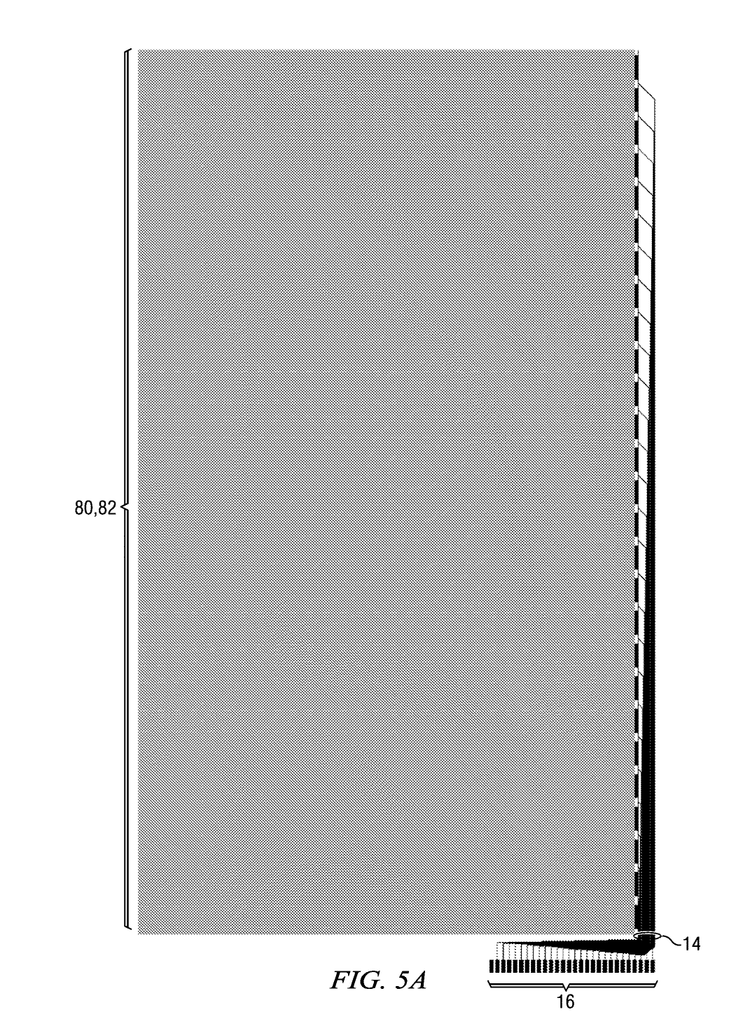

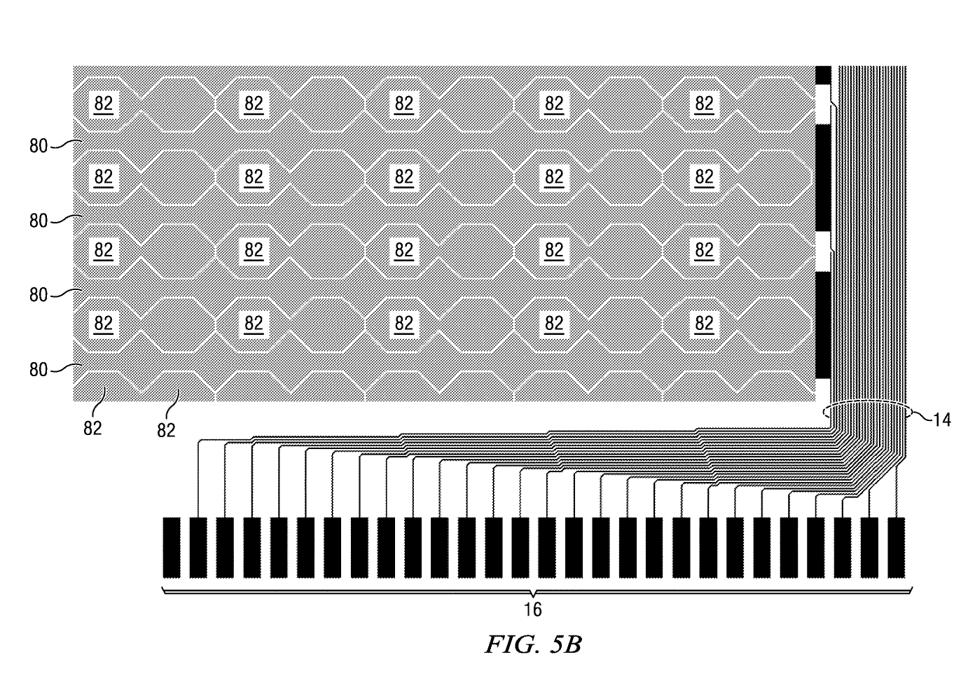

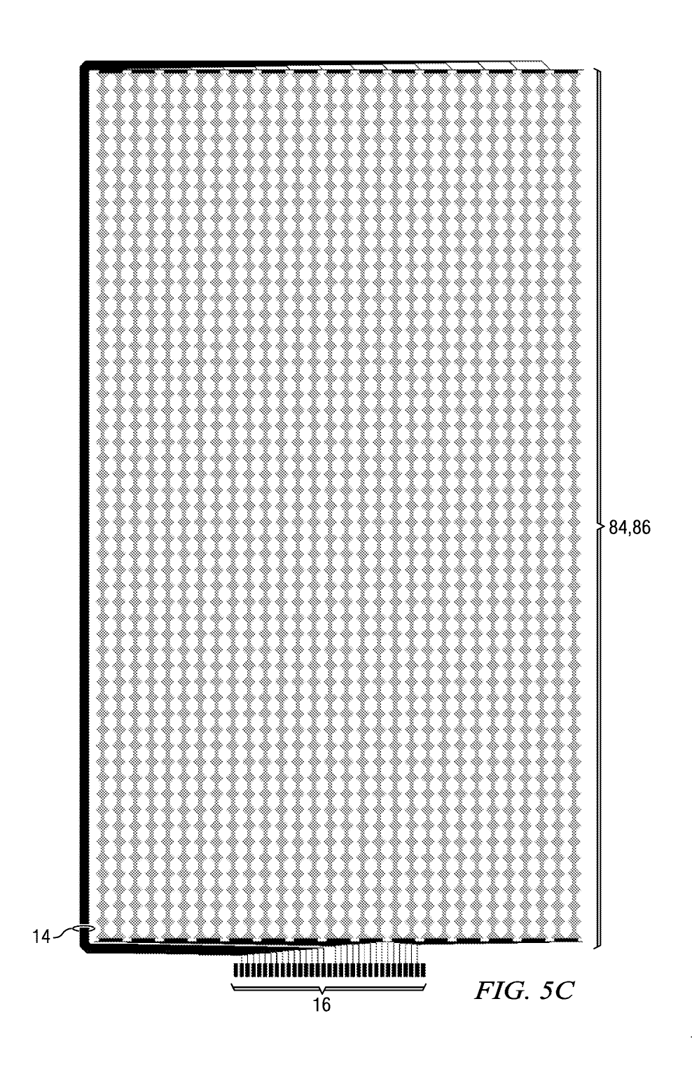

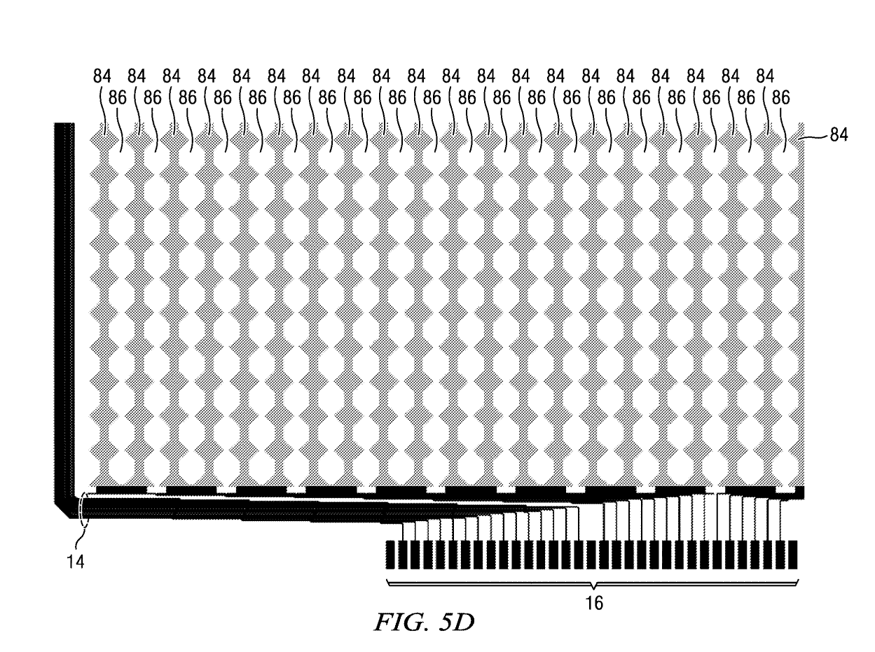

FIGS. 5A-5D illustrate another example self-shielding co-planar touchscreen design on two layers. The touchscreen design of FIGS. 5A-5D includes an example diamond pattern. FIG. 5A illustrates a top layer of the design, and FIG. 5B provides a close-up view of a portion of the top layer in FIG. 5A. FIG. 5C illustrates a bottom layer of the design, and FIG. 5D provides a close-up view of a portion of the bottom layer in FIG. 5C. In the example of FIGS. 5A-5D, the top layer of the design (illustrated by FIGS. 5A-5B) includes X electrodes 80 and floating electrodes 82. The bottom layer of the design (illustrated by FIGS. 5C-5D) includes Y electrodes 84 and ground electrodes 86.

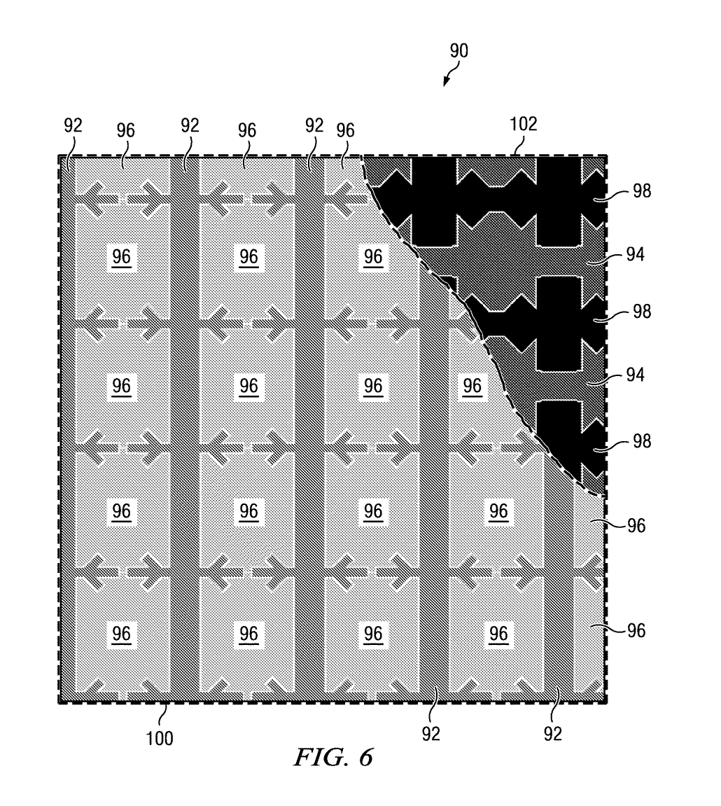

FIG. 6 illustrates another example self-shielding co-planar touchscreen design 90 on two layers. FIG. 6 provides a top-down view of both layers, with portion 100 illustrating a portion of the top layer and portion 102 illustrating a portion of the bottom layer. Touchscreen design 90 includes an example snowflake design. In touchscreen design 90, a top layer includes Y electrodes 92 and a bottom layer includes X electrodes 94. The top layer also includes floating electrodes 96, and the bottom layer also includes ground electrodes 98. Floating electrodes 96 and ground electrodes 98 may be made of the same material as Y and X electrodes 92 and 94. The material on the top layer may be cut or etched to form the pattern of Y electrodes 92 and floating electrodes 96 in the example of FIG. 6, and the material on the bottom layer may be similarly cut or etched to form the pattern of X electrodes 94 and ground electrodes 98 in the example of FIG. 6. Floating electrodes 96 allow for more consistent coupling between X electrodes 94 and Y electrodes 98 beneath them and ground electrodes 98 provide shielding for Y electrodes 92 above them. In particular embodiments, floating electrodes 96 and ground electrodes 98 embody the same or a similar snowflake pattern as Y and X electrodes 92 and 94, but with larger corresponding shapes than the electrodes that they are opposite to. Floating electrodes 96 are cut or etched to be electrically isolated. Ground electrodes 98 are cut or etched to form lines running parallel to X electrodes 94.

Particular embodiments incorporate one or more components, elements, features, functions, method, operations, or steps described or illustrated in the attachment hereto.

Herein, reference to a computer-readable non-transitory storage medium or media may include one or more semiconductor-based or other integrated circuits (ICs) (such, as for example, a field-programmable gate array (FPGA) or an application-specific IC (ASIC)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards, SECURE DIGITAL drives, any other suitable computer-readable non-transitory storage medium or media, or any suitable combination of two or more of these, where appropriate. A computer-readable non-transitory storage medium or media may be volatile, non-volatile, or a combination of volatile and non-volatile, where appropriate. A computer-readable non-transitory storage medium or media may embody logic that is configured when executed to control a specific device or component thereof such as, for example and not by way of limitation, a touch sensor or touchscreen.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, functions, operations, or steps, any of these embodiments may include any combination or permutation of any of the components, elements, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A touch sensor comprising:
a plurality of first electrodes on a first surface, wherein the first electrodes comprise a first shape;
a plurality of second electrodes on a second surface, wherein the second electrodes comprise a second shape;
a plurality of third electrodes on the first surface, wherein the third electrodes comprise a third shape that encompasses the second shape and are positioned on the first surface opposite the second electrodes; and
a plurality of fourth electrodes on the second surface, wherein the fourth electrodes comprise a fourth shape that encompasses the first shape and are positioned on the second surface opposite the first electrodes.

2. The touch sensor of claim 1, wherein:
the first electrodes are sense electrodes;
the second electrodes are drive electrodes;
the third electrodes are floating electrodes; and
the fourth electrodes are ground electrodes.

3. The touch sensor of claim 1, wherein the first and second surfaces are opposite surfaces of a single substrate.

4. The touch sensor of claim 1, wherein:
the first surface is a surface of a first substrate; and
the second surface is a surface of a second substrate.

5. The touch sensor of claim 1, wherein:
the third shape is equivalent to but larger than the second shape; and
the fourth shape is equivalent to but larger than the first shape.

6. The touch sensor of claim 1, wherein the first electrodes embody a diamond pattern.

7. The touch sensor of claim 1, wherein the first electrodes embody a snowflake pattern.

8. The touch sensor of claim 1, wherein:
the first and third electrodes were cut or etched from a substantially continuous first layer of conductive material deposited on the first surface; and
the second and fourth electrodes were cut or etched from a substantially continuous second layer of conductive material deposited on the second surface.

9. A device comprising:
a touch sensor that comprises:
a plurality of first electrodes on a first surface, wherein the first electrodes comprise a first shape;
a plurality of second electrodes on a second surface, wherein the second electrodes comprise a second shape;
a plurality of third electrodes on the first surface, wherein the third electrodes comprise a third shape that encompasses the second shape and are positioned on the first surface opposite the second electrodes; and
a plurality of fourth electrodes on the second surface, wherein the fourth electrodes comprise a fourth shape that encompasses the first shape and are positioned on the second surface opposite the first electrodes; and
a computer-readable non-transitory storage medium embodying logic that is configured when executed to control the touch sensor.

10. The device of claim 9, wherein:
the first electrodes are sense electrodes;
the second electrodes are drive electrodes;
the third electrodes are floating electrodes; and
the fourth electrodes are ground electrodes.

11. The device of claim 9, wherein the first and second surfaces are opposite surfaces of a single substrate.

12. The device of claim 9, wherein:
the first surface is a surface of a first substrate; and
the second surface is a surface of a second substrate.

13. The device of claim 9, wherein:
the third shape is equivalent to but larger than the second shape; and
the fourth shape is equivalent to but larger than the first shape.

14. The device of claim 9, wherein the first electrodes embody a diamond pattern.

15. The device of claim 9, wherein the first electrodes embody a snowflake pattern.

16. The device of claim 9, wherein:
the first and third electrodes were cut or etched from a substantially continuous first layer of conductive material deposited on the first surface; and
the second and fourth electrodes were cut or etched from a substantially continuous second layer of conductive material deposited on the second surface.

17. A computer-readable non-transitory storage medium embodying logic that is configured when executed to control a touch sensor that comprises:
a plurality of first electrodes on a first surface, wherein the first electrodes comprise a first shape;
a plurality of second electrodes on a second surface, wherein the second electrodes comprise a second shape;
a plurality of third electrodes on the first surface, wherein the third electrodes comprise a third shape that encompasses the second shape and are positioned on the first surface opposite the second electrodes; and
a plurality of fourth electrodes on the second surface, wherein the fourth electrodes comprise a fourth shape that encompasses the first shape and are positioned on the second surface opposite the first electrodes.

18. The medium of claim 17, wherein:
the first electrodes are sense electrodes;
the second electrodes are drive electrodes;
the third electrodes are floating electrodes; and
the fourth electrodes are ground electrodes.

19. The medium of claim 17, wherein the first and second surfaces are opposite surfaces of a single substrate.

20. The medium of claim 17, wherein:
the first surface is a surface of a first substrate; and
the second surface is a surface of a second substrate.
